(19) United States
(12) Patent Application Publication
(10) Pub. No.: US 2004/0027033 A1
(43) Pub. Date: Feb. 12, 2004

(54) Solid-state acceleration sensor device and method

(76) Inventor: Peter J. Schiller, Coon Rapids, MN (US)

Correspondence Address: Min S. (Amy) Xu, DORSEY & WHITNEY LLP, Suite 1500, 50 South Sixth Street, Minneapolis, MN, 55402-7367, US

(21) Appl. No.: 10/636,051

(22) Filed: Aug. 7, 2003

Related U.S. Application Data
(60) Provisional application No. 60/401,927, filed on Aug. 8, 2002.

(51) Int. Cl. H01L 41/04

(52) U.S. Cl. 310/329

(57) ABSTRACT

The present invention provides a solid-state acceleration sensor device formed by thin films for generating an electrical voltage output proportional to acceleration motion. The precision thin-film piezoelectric elements are configured and arranged on a semi-rigid structure to detect acceleration while rejecting spurious noise created by package strain, thermal gradients, and electromagnetic interference.

### CROSS-REFERENCE TO RELATED APPLICATION(S)

The present utility patent application claims priority of U.S. Provisional Patent Application, Serial No. 60/401,927, filed Aug. 8, 2002, subject matter of which is incorporated herewith by reference.

### FIELD OF THE INVENTION

The present invention relates generally to a piezoelectric accelerometer device and method, and more particularly, to a solid-state piezoelectric sensor device and method for measuring acceleration.

### BACKGROUND OF THE INVENTION

Piezoelectric materials are used in a variety of sensors and actuators. Piezoelectric materials convert mechanical energy to electrical energy and vice versa. For instance, if pressure is applied to a piezoelectric crystal, an electrical signal is generated in proportion thereby producing the function of a sensor. Generation of an electrical signal in response to an applied force or pressure is known as the “primary piezoelectric effect”. Similarly, if an electrical signal is applied to a piezoelectric crystal, it will expand in proportion as an actuator. Geometric deformation (expansion or contraction) in response to an applied electric signal is known as the “secondary piezoelectric effect”. Whether operated as a sensor or actuator, electrically-conductive electrodes must be appropriately placed on the piezoelectric crystal for collection or application of the electrical signal, respectively. Therefore, a piezoelectric sensor (actuator) consists nominally of a) a portion of piezoelectric material, and b) electrically-conductive electrodes suitably arranged to transfer electrical energy to (from) an external power source.

Piezoelectric materials have been utilized to create a variety of simple sensors and actuators. Examples of sensors include vibration sensors, microphones, and ultrasonic sensors. Examples of actuators include ultrasonic transmitters and linear positioning devices. However, in most of these examples, bulk piezoelectric material is machined and assembled in a coarse manner to achieve low-complexity devices.

Existing vibrating acceleration sensors combine a forced vibration motion with a static acceleration to generate a secondary vibration that is proportional to the static acceleration. Existing vibrating accelerometer devices generate a primary vibration motion along a first axis direction, and measure the amplitude of secondary vibration along a second axis direction. The amplitude of secondary vibration is proportional to the acceleration along said second axis direction. In existing vibrating accelerometers, the amplitude of secondary vibration is measured as an indicator of acceleration. Sensors convert the amplitude of secondary vibration into an electrical signal proportional to the acceleration. However, the amplitude of secondary vibration is also responsive to temperature, package strain, electromagnetic interference and other undesirable effects that corrupt the accelerometer data.

The existing vibrating acceleration sensors rely on single-ended actuation and sensors to produce and measure the vibrational motion. Single-ended sensors are generally responsive to temperature, package strain, electromagnetic interference and other undesirable effects that corrupt the sensor data. Single-ended actuators provide less accuracy in controlling the vibrational motion.

Therefore, there is a need for an improved piezoelectric acceleration sensor device and method.

### SUMMARY OF THE INVENTION

To solve the above and the other problems, the present invention provides a solid-state acceleration sensor device. Similar to silicon Integrated Circuits (ICs), an acceleration sensor device is built up by a series of thin films, typically less than or about 10 micron (0.01 mm) in thickness. An accelerometer is designed to generate an electrical signal output proportional to acceleration.

The present invention provides precision thin-film piezoelectric elements on a semi-rigid structure to detect acceleration while rejecting spurious noise created by package strain, thermal gradients, and electromagnetic interference. During normal operation, selected piezoelectric elements on the accelerometer structure are driven by a first periodic electrical signal to create a controlled mechanical oscillation. When the accelerometer is subjected to acceleration, a characteristic second electrical signal is produced across other piezoelectric elements on the accelerometer, according to the primary piezoelectric effect. These second electrical signals are amplified and filtered through associated electrical circuitry to extract high-fidelity electrical signals proportional to the acceleration.

In one embodiment, the present invention utilizes piezoelectric materials in a thin-film format. The thin-film distinction enables sensors with a far higher degree of complexity and accuracy. Thin-films offer the following key advantages:

Matching—Thin-film piezoelectric materials are deposited and defined on an atomic scale utilizing fabrication processes common in the semiconductor industry. The result is that thin-film piezoelectric elements can be consistently manufactured with element matching more than 100× better than conventional bulk machined devices.

Density—Thin-film piezoelectric elements are defined using microlithography, a process which enables extremely small dimensions (less than 0.001 mm, or 1 micron) to be delineated in a consistent and controlled manner. The result is that a large number of precision piezoelectric elements can be defined on a single microscopic transducer device.

Accuracy—In a thin-film format, piezoelectric materials exhibit reduced levels of random noise. At system level, the effect of lower noise is higher accuracy readings.

Low-Cost—Thin-film piezoelectric elements are defined using batch processing techniques common in the semiconductor industry. A typical deposition, pattern transfer, and etch sequence on a single silicon wafer defines literally millions of precision piezoelectric elements on thousands of transducers.

Size—Thin-film piezoelectrics enable far smaller devices to be manufactured

Low Power—Less energy is required to operate a thin-film device

The present invention further provides differential piezoelectric elements for sensing and driving the vibrational motion of the acceleration sensor. Differential elements provide improved immunity to temperature, package strain, electromagnetic interference and other undesirable effects that corrupt sensor data in existing acceleration sensor devices.

The present invention further provides a method for detecting acceleration based on the phase shift between the secondary and primary vibrational motions in a vibrating accelerometer. By measuring the phase shift of the accelerometer output signals, further immunity to temperature, package strain, electromagnetic interference and other undesirable effects is achieved.

The present invention further provides a method for detecting acceleration based on the shift of resonant frequency in a vibrating accelerometer. By measuring the shift of the accelerometer resonant frequency, further immunity to temperature and manufacturing variation is achieved.

The above advantages are inherent to the present invention and enable novel configurations and unique features that increase the overall device and system performance.

These and other features and advantages of the present invention will become apparent to those skilled in the art from the following detailed description, wherein it is shown and described illustrative embodiments of the invention, including best modes contemplated for carrying out the invention. As it will be realized, the invention is capable of modifications in various obvious aspects, all without departing from the spirit and scope of the present invention. Accordingly, the drawings and detailed description are to be regarded as illustrative in nature and not restrictive.

### BRIEF DESCRIPTION OF THE DRAWINGS

FIG. 1 is a cross-sectional view of one embodiment of a solid-state vibrating acceleration sensor device, in accordance with the principles of the present invention.

FIG. 2 is a top view of one embodiment of the solid-state vibrating acceleration sensor device showing one arrangement of piezoelectric element placement.

FIG. 3 is a block diagram of one embodiment of a two-axis solid-state vibrating acceleration sensor device electrical configuration for simple parallel connection of symmetric and differential elements with feedback for z-axis vibration control, illustrating single-ended actuator drive and actuator sense.

FIG. 4 is a block diagram of another embodiment of an one-axis solid-state vibrating acceleration sensor device electrical configuration for simple parallel connection of symmetric and differential elements with feedback for in-plane vibration control using electrode configuration of FIG. 2, illustrating differential actuator drive and actuator sense.

FIG. 5 is a top view of one embodiment of a solid-state vibrating acceleration sensor device showing another arrangement of piezoelectric element placement.

FIG. 6 is a block diagram of one embodiment of a two-axis solid-state vibrating acceleration sensor device electrical configuration for simple parallel connection of symmetric and differential elements with feedback for out-of-plane vibration control using electrode configuration of FIG. 5, illustrating differential actuator drive and actuator sense.

FIG. 7 is a block diagram of one embodiment of a one-axis solid-state vibrating acceleration sensor device electrical configuration of FIG. 4 with addition of bias voltage circuitry for resonant frequency shifting.

FIG. 8 is a block diagram of one embodiment of a one-axis solid-state vibrating acceleration sensor device electrical configuration for phase shift detection using a differential actuator drive and differential actuator sense.

FIG. 9 is a schematic view of phase shift of vibrating acceleration sensor transverse electrical output signal relative to vibrating acceleration sensor actuator sense output signal and associated output electrical signal from a phase-shift detector of FIG. 8, illustrating oscillating voltage signals versus time for several different acceleration conditions operated in a one-axis solid-state vibrating acceleration sensor device, in accordance with the principles of the present invention.

FIG. 10 is a block diagram of an analog phase-shift detector circuit with feedback for output stabilization, in accordance with the principles of the present invention.

FIGS. 11(a), 11(b), and 11(c) are schematic views of electrical signals in the phase-shift detector circuit of FIG. 10, representing for 11(a) no acceleration, 11(b) positive acceleration, and 11(c) negative acceleration.

### DETAILED DESCRIPTION OF THE PREFERRED EMBODIMENTS

The present invention provides a solid-state acceleration sensor device formed by thin films for generating an electrical signal output proportional to acceleration. The precision thin-film piezoelectric elements are configured and arranged on a semi-rigid structure to detect acceleration while rejecting spurious noise created by package strain, thermal gradients, and electromagnetic interference.

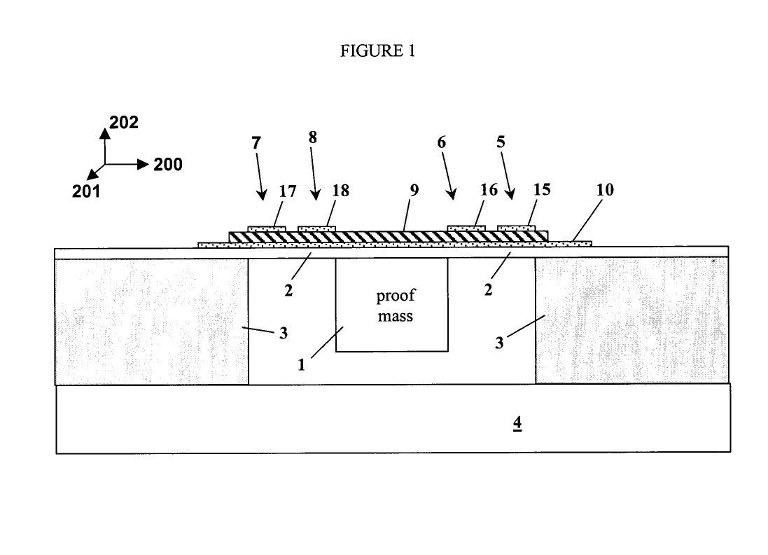

The main features of one embodiment of a vibrating acceleration sensor device (also referred to as “accelerometer”) are shown in FIG. 1. The device includes a) a cylindrical silicon proof-mass 1 that is suspended on b) a toroidal thin-film membrane 2 on which are c) a series of thin-film piezoelectric elements 5, 6, 7, and 8. Typically, the height of the proof-mass 1 is about 500 microns, the diameter of the proof-mass 1 is about 400 microns, while the outer diameter of the membrane 2 toroid is about 700 microns. The membrane 2 can be realized with a variety of different materials that exhibit flexibility, resistance to fatigue, and good thermal expansion match to the surrounding silicon substrate 3. The silicon substrate 3 is mounted on a base support 4. Preferred materials for the membrane 2 are single-crystal silicon, polycrystalline silicon, and silicon nitride with a typical thickness of about 1 micron. However, some high frequency or high range sensors would utilize a much thicker membrane 2. The device depicted in FIG. 1 has four separate piezoelectric elements (5-8) that share a common piezoelectric film 9 and a lower conductive layer or electrode 10, but are delineated by the separate upper electrodes (15-18). The piezoelectric elements 5-8 are formed from a single conductive layer (preferably platinum about 0.1 microns thick) that forms a common lower layer 10, a single layer of piezoelectric thin film 9 (preferably PZT about 1 micron thick), and separate upper conducive electrodes 15-18. By utilizing a single common layer for the lower layer 10 and piezoelectric film 9, matching between elements and element density is increased; these factors improve the accelerometer's signal fidelity. The piezoelectric elements are defined by upper conductive electrodes 15, 16, 17, and 18 (preferably platinum about 0.1 microns thick). Each piezoelectric element is comprised of an upper conductive electrode along with a portion of the piezoelectric film and a lower conductive electrode that reside beneath the upper conductive electrode. For example, the piezoelectric element 5 is comprised of the electrode 15 along with a portion of piezoelectric film and a lower conductive electrode that reside beneath the electrode 15. Since the piezoelectric film 9 is non-conductive, each piezoelectric element 5-8 is defined by the upper conductive electrodes 15-18 alone, and electrical interaction between piezoelectric elements is negligible.

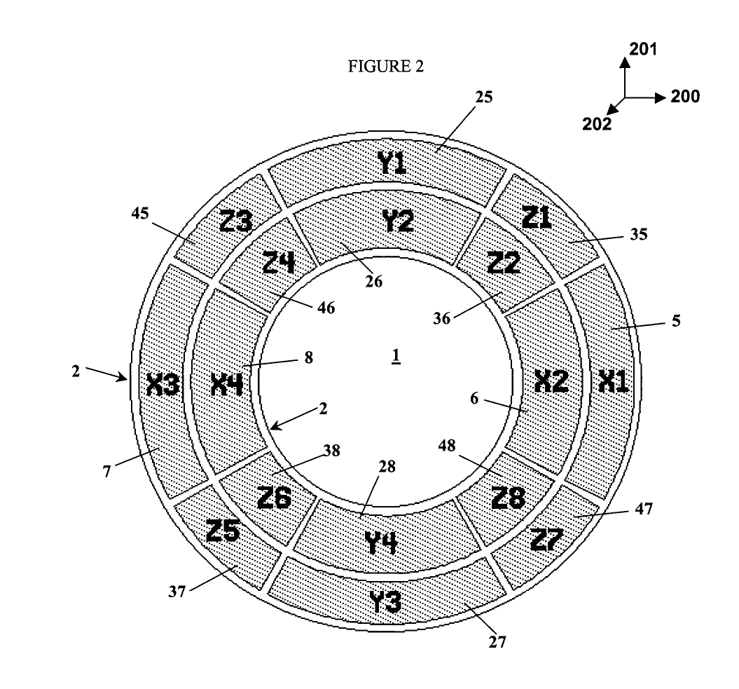

A first embodiment of piezoelectric element configuration for a solid-state vibrating acceleration sensor device is detailed in FIG. 2, and it includes matched differential element pairs (i.e. 5 and 6) that reside on adjacent inner and outer regions of the membrane toroid 2. Each differential element pair is configured for optimal matching; they have identical electrode area, are placed at minimum spacing, and are symmetrically located on the semi-rigid toroidal membrane 2. In addition, an identical mirror-image differential element pair is located on the opposite side of the proof-mass 1 (i.e. element pair 5/6 and element pair 7/8 represent a mirror-image pair). During operation as a sensor, these 4-element mirror-image pairs will selectively generate differential electrical signals associated with motion along a single coordinate axis. During operation as an actuator, these 4-element mirror-image pairs will selectively generate motion along a single coordinate axis. Whether operated as a sensor or actuator, the differential nature and symmetric placement along the coordinate axes allows motion in other directions to be rejected, thereby increasing the signal accuracy. The amount of “off-axis rejection” is strongly related to a) the symmetry b) matching of the elements, and c) precision placement. These are some of the key advantages of the present invention that yield dramatically improved performance over existing acceleration sensor devices. A multitude of additional electrode configurations can be used within the scope of the present invention and are known in the electrical art. The arrangement of FIG. 2 depicts one of many suitable centro-symmetric (symmetry in a cylindrical coordinate system) arrangements of differential piezoelectric elements.

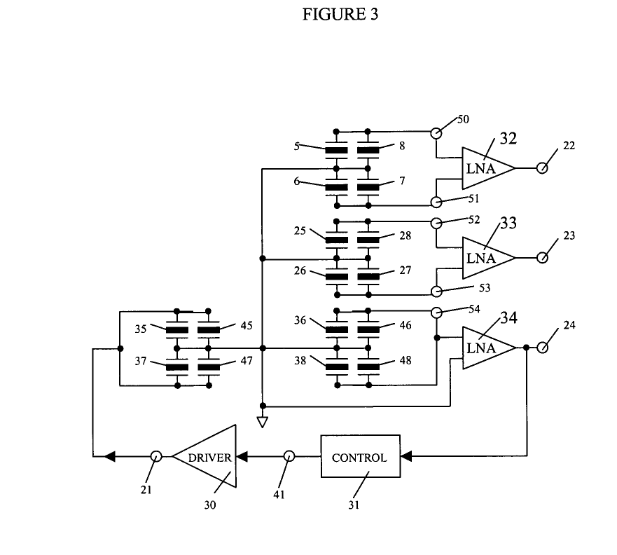

Operation of an acceleration sensor device shown in FIGS. 1 and 2 is based on the superposition of a first vibration motion with an acceleration. In a first mode of operation, the accelerometer is connected electrically to several electronic components as shown in FIG. 3. In the electrical configuration of FIG. 3, a periodic voltage 21 is applied simultaneously by a voltage driver circuit 30 to elements 35, 45, 37, and 47. By the secondary piezoelectric effect, the membrane 2 under these four elements is deflected or bent, and the proof mass is driven into primary vibration along the direction 202 (perpendicular to the surface, see FIG. 2) at the same periodic rate as the applied voltage 21. If an acceleration motion is applied to the accelerometer along the direction 201, a secondary vibration forms in the direction 201. Similarly, if an acceleration motion is applied to the accelerometer along the direction 200, a secondary vibration forms in the direction 200. The secondary vibrations are proportional to the magnitude of primary vibration and the acceleration.

The piezoelectric elements 5, 6, 7, and 8 (elements 5-8) detect the secondary vibration along the direction 200 that is associated with acceleration along the direction 200, and generate a differential pair of electrical signals 50 and 51, the difference being proportional to the acceleration. A low-noise amplifier (LNA) 32 boosts/amplifies the differential electrical signals 50 and 51 level from elements 5-8 to create an output signal 22. The piezoelectric elements 25, 26, 27, and 28 (elements 25-28) detect the secondary vibration along the direction 201 that is associated with acceleration along the direction 201, and generate a differential pair of electrical signals 52 and 53 in proportion to the acceleration. A low-noise amplifier (LNA) 33 boosts the electrical signal 52 and 53 levels from the elements 25-28 to create an output signal 23. In the embodiment of FIGS. 1-3, elements 36, 46, 38, and 48 are connected together and operate as sensors that generate a single-ended electrical signal 54 proportional to the primary vibration along the direction 202.

A low-noise amplifier 34 boosts the level of the electrical signal 54 from the elements 36, 46, 38, and 48 to create an output reference signal 24. Control electronics 31 process the electrical signal 24 by adding appropriate signal gain (or attenuation) and phase shift such that a stable periodic signal is sent to the voltage driver circuit 30. This feedback mode of operation provides immunity to temperature variation and other environmental anomalies and improves the overall fidelity of the acceleration sensor performance. Again, the quality of piezoelectric matching and symmetry enable this mode of operation.

In the embodiment of FIGS. 1-3 and many other embodiments of the present invention, it may be desirable to drive an actuator (elements 35, 37, 45, and 47) at the fundamental mechanical resonant frequency associated with proof-mass 1 motion in the direction 202. Operation at the resonant frequency provides a maximum amount of motion with the minimum applied signal voltage. According to the primary piezoelectric effect and details of the mechanical resonant behavior, the amplitude and phase of the output electrical signal 24 shift relative to the applied drive voltage 21 at the associated mechanical resonant frequency.

The control electronics 31 provide appropriate phase shift and electrical signal gain (according to the Nyquist criteria) to selectively force the periodic signal to match the mechanical resonant frequency. The details of the control electronics 31 are well understood in the field and not a subject of the present invention.

It is noted that the embodiment shown in FIGS. 1-3 and described above may be varied because the actuation contributed by the elements 35, 37, 45, and 47 is driven with a single-ended signal 21, and the actuation sense contributed by elements 36, 38, 46, and 48 provides a single-ended electrical signal 54. Single-ended signals do not generally provide optimal signal fidelity. A single-ended arrangement is responsive to the intended oscillation, but it is also responsive to a multitude of other unintended artifacts, such as stray electric fields, temperature, package strain, capacitive charge injection, etc. Furthermore, the single-ended motor arrangement may not optimally match the resonant vibration pattern.

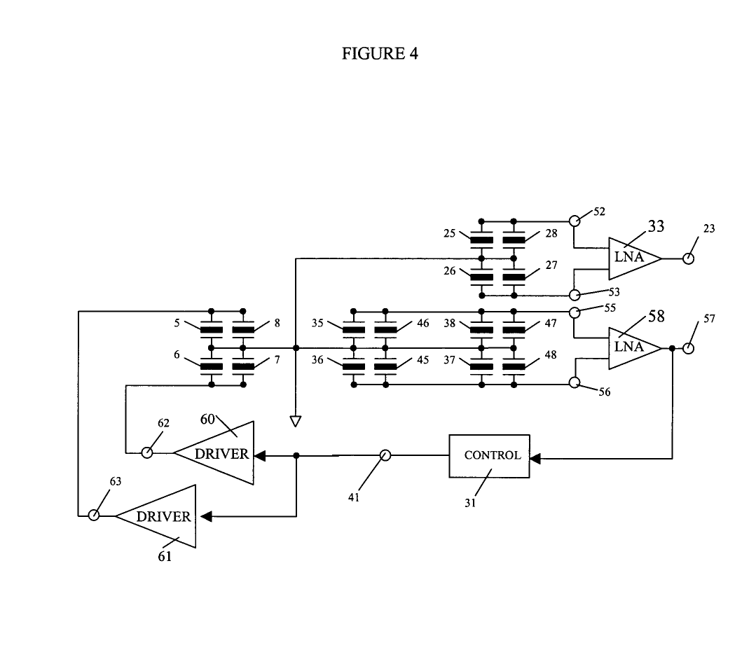

A differential arrangement can be configured to reject most signals except for the intended oscillation response, thereby improving the fidelity and selectivity of the acceleration sensor. Improved overall device performance can be achieved if either the actuator (elements 35, 37, 45, 47 in FIG. 3), the actuator sense (elements 36, 38, 46, 48 in FIG. 3), or both are instead implemented in a differential configuration. In a preferred embodiment for a single-axis acceleration sensor, the device depicted in FIGS. 1-2 is connected to the electrical circuit as shown in FIG. 4 to achieve both a differential motor and differential motor sense.

In the electrical configuration of FIG. 4, the control electronics 31 apply a periodic control signal 41 to a non-inverting voltage driver circuit 60 and an inverting voltage driver circuit 61. The non-inverting voltage driver circuit 60 generates a positive actuator drive electrical signal 62 that is connected to actuator elements 6 and 7. The inverting voltage driver circuit 61 generates a negative actuator drive electrical signal 63 that is connected to actuator elements 5 and 8, and is approximately 180 degrees out of phase with the positive actuator drive electrical signal 62. By the secondary piezoelectric effect, the membrane under the elements 6 and 7 is bent upward (or downward) while the membrane under the elements 5 and 8 is bent downward (or upward). The net result is a tilting of the proof mass 1 (shown in FIG. 1) along the direction 200. As the periodic control signal 41 alternates, the proof mass 1 vibrates along the direction 200 in proportion to and at the oscillation rate of the periodic control signal 41. If the device is electrically configured as shown in FIG. 4 with proof mass 1 primary vibration along the direction 200 and an acceleration motion is applied to the accelerometer along the direction 201, a secondary vibration forms in the direction 201. The secondary vibration is proportional to the magnitude of primary vibration, and the acceleration. The piezoelectric elements 25, 26, 27, and 28 generate a differential pair of electrical signals 52 and 53 proportional to the secondary vibration along the direction 201 that is associated with acceleration along the direction 201.

A low-noise amplifier 33 boosts the differential electrical signals 52 and 53 to create an output signal 23 which is proportional to the acceleration along the direction 201.

In the embodiment of FIG. 4 (reference to FIGS. 1 and 2), the elements 35-38 and 45-48 create the actuation sense function and are connected in a differential arrangement to generate differential electrical signals 55 and 56 proportional to the primary vibration along the direction 200. With the piezoelectric element embodiment of FIG. 2 connected as shown in FIG. 4, the elements 35, 46, 38, and 47 mirror the behavior of actuator elements 5 and 8. For instance, the elements 35, 46, 38, and 47 are bent upward when the actuator elements 5 and 8 are bent upward, and the elements 35, 46, 38, and 47 are bent downward when the actuator elements 5 and 8 are bent downward. Similarly, with the piezoelectric element embodiment of FIG. 2 connected as shown in FIG. 4, the elements 36, 45, 37, and 48 mirror the behavior of the actuator elements 6 and 7. For instance, the elements 36, 45, 37, and 48 are bent upward when the actuator elements 6 and 7 are bent upward, and the elements 36, 45, 37, and 48 are bent downward when the actuator elements 6 and 7 are bent downward. Collectively, the elements 35-38 and 45-48 generate the differential actuation sense electrical signals 55 and 56 which is subsequently boosted by a low-noise amplifier 58 to create an output reference signal 57.

Control electronics 31 process the electrical signal 57 by adding appropriate signal gain (or attenuation) and phase shift such that a stable periodic signal is sent to the voltage driver circuits 60 and 61. This feedback mode of operation provides immunity to temperature variation and other environmental anomalies and improves the overall fidelity of the acceleration sensor performance. Again, the quality of piezoelectric matching and symmetry enable this mode of operation.

In the embodiment of FIG. 4 and many other embodiments of the present invention, it may be desirable to drive the actuator elements 5, 6, 7, 8 at the fundamental mechanical resonant frequency associated with the proof-mass 1 motion in the direction 200. Operation at the resonant frequency provides a maximum amount of motion with the minimum applied signal voltage. According to the primary piezoelectric effect and details of the mechanical resonant behavior, the amplitude and phase of the output signal 57 shift relative to the periodic control signal 41 at the mechanical resonant frequency along the direction 200. The control electronics 31 provide appropriate phase shift and electrical signal gain (according to the Nyquist criteria) to selectively force the periodic signal to match the mechanical resonant frequency along the direction 200. The details of the control electronics 31 are well understood in the field and not a subject of the present invention.

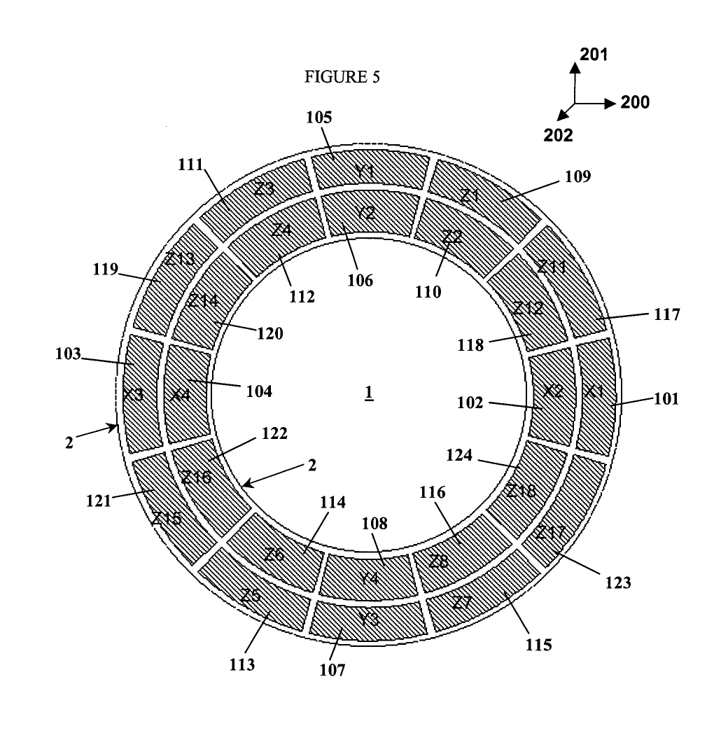

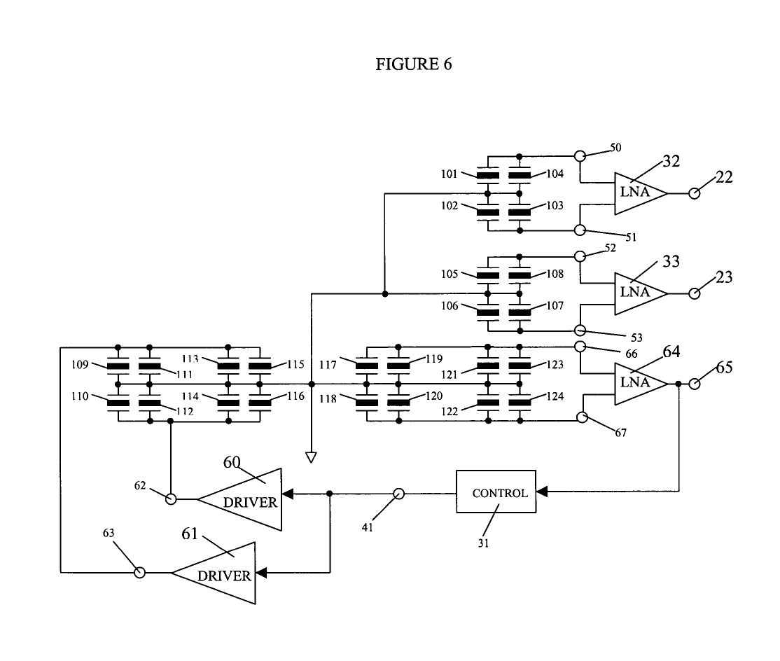

In a preferred embodiment for a dual-axis acceleration sensor, the device depicted in FIGS. 1 and 5 is connected to the electrical circuit shown in FIG. 6 to achieve both a differential actuator and differential actuation sense. In the electrical configuration of FIG. 6, the control electronics 31 apply a periodic control signal 41 to a non-inverting voltage driver circuit 60 and an inverting voltage driver circuit 61. The non-inverting voltage driver circuit 60 generates a positive actuator drive electrical signal 62 that is connected to actuator elements 110, 112, 114, and 116. The inverting voltage driver circuit 61 generates a negative actuator drive electrical signal 63 that is connected to actuator elements 109, 111, 113, and 115, and is approximately 180 degrees out of phase with the positive actuator drive electrical signal 62. By the secondary piezoelectric effect, the membrane 2 under the actuator elements 109, 111, 113, and 115 is bent upward (or downward) while the membrane 2 under the actuator elements 110, 112, 114, and 116 is bent downward (or upward). The net result is a deflection of the proof mass 1 (shown in FIG. 1) along the direction 202. As the periodic control signal 41 alternates, the proof mass 1 vibrates along the direction 202 in proportion to and at the oscillation rate of the periodic control signal 41.

If the device is electrically configured as shown in FIG. 6 with the proof mass 1 vibration along the direction 202 and an acceleration motion is applied to the acceleration sensor along the direction 201, a secondary vibration forms in the direction 201. The secondary vibration along the direction 201 is proportional to the magnitude of primary vibration, and the acceleration along the direction 201. The piezoelectric elements 105, 106, 107, and 108 generate differential electrical signals 52 and 53 proportional to the secondary vibration along the direction 201 that is associated with acceleration along the direction 201.

A low-noise amplifier 33 boosts the differential electrical signal levels 52 and 53 to create an output signal 23 which is proportional to the acceleration along the direction 201.

If the device is electrically configured as shown in FIG. 6 with proof mass 1 primary vibration along the direction 202 and an acceleration motion is applied to the acceleration sensor along the direction 200, a secondary vibration forms in the direction 200. The secondary vibration is proportional to the magnitude of primary vibration along the direction 202, and the acceleration along the direction 200. The piezoelectric elements 101, 102, 103, and 104 generate differential electrical signals 50 and 51 proportional to the secondary vibration along the direction 200 that are associated with acceleration along the direction 200.

A low-noise amplifier 32 boosts the differential electrical signals 50 and 51 to create an output signal 22 which is proportional to the acceleration motion along the direction 200.

In the embodiment of FIG. 6 (reference to FIGS. 1 & 5), elements 117-124 create the actuator sense function and are connected in a differential arrangement to generate differential electrical signals 66 and 67 proportional to the primary vibration along the direction 202. With the piezoelectric element embodiment of FIG. 5 connected as shown in FIG. 6, the elements 117, 119, 121, and 123 mirror the behavior of the actuator elements 109, 111, 113, and 115. For instance, the elements 117, 119, 121, and 123 are bent upward when the actuator elements 109, 111, 113, and 115 are bent upward, while the elements 117, 119, 121, and 123 are bent downward when the actuator elements 109, 111, 113, and 115 are bent downward. Similarly, with the piezoelectric element embodiment of FIG. 5 connected as shown in FIG. 6, the elements 118, 120, 122, and 124 mirror the behavior of the actuator elements 110, 112, 114, and 116. For instance, the elements 118, 120, 122, and 124 are bent upward when the actuator elements 110, 112, 114, and 116 are bent upward, and the elements 118, 120, 122, and 124 are bent downward when the actuator elements 110, 112, 114, and 116 are bent downward. Collectively, the elements 117-124 generate the differential actuation sense electrical signals 66 and 67 which are subsequently boosted by a low-noise amplifier 64 to create an output reference signal 65.

Control electronics 31 process the output reference electrical signal 65 by adding appropriate signal gain (or attenuation) and phase shift such that a stable periodic signal is sent to the voltage driver circuits 60 and 61. This feedback mode of operation provides immunity to temperature variation and other environmental anomalies and improves the overall fidelity of the acceleration sensor performance. Again, the quality of piezoelectric matching and symmetry enable this mode of operation.

In the embodiment of FIG. 6 and many other embodiments of the present invention, it may be desirable to drive the actuator elements 109-116 at the fundamental mechanical resonant frequency associated with proof-mass 1 motion in the direction 202. Operation at the resonant frequency provides a maximum amount of motion with the minimum applied signal voltage. According to the primary piezoelectric effect and details of the mechanical resonant behavior, the amplitude and phase of the signal 65 shifts relative to the periodic control signal 41 at the mechanical resonant frequency of motion along the direction 202.

Control electronics 31 provide appropriate phase shift and electrical signal gain (according to the Nyquist criteria) to selectively force the periodic signal 41 to match the mechanical resonant frequency. The details of the control electronics 31 are well understood in the field and not a subject of the present invention.

In the discussion of acceleration sensor operation, circuit operation, and piezoelectric effects, the terms “voltage” and “electrical signal” have been used intermittently. In general, “electrical signal” is a general term that may describe an electric potential difference (or voltage), an electrical current, or an electrical charge. Depending on the details of the electric circuits connected to the acceleration sensor (such as “LNA”, “control electronics”, and “voltage driver circuits”), the actual electrical signals involved in acceleration sensor operation may be best described as a “voltage”, a “current”, or a “charge”. For instance, the low noise amplifiers may be implemented with voltage amplifiers in which case the electrical signals generated by the piezoelectric elements is best described as a voltage. Conversely, the low noise amplifiers may be implemented with charge amplifiers in which case the electrical signals generated by the piezoelectric elements is best described as a charge or current. The terminology used herein with respect to electrical signals is not intended to limit the scope of the present invention.

Operation of the acceleration sensor at the mechanical resonant frequency along the drive (actuator) axis provides maximum performance since the acceleration output signals are proportional to the amplitude of primary vibration along the actuator axis (direction 200 in FIG. 2). The control electronics 31 in FIGS. 4 and 6 ensures mechanical vibration at actuator axis resonant frequency. Additionally, the secondary vibration signal can be further increased if the device can simultaneously be operated at the mechanical resonant frequency associated with the axis along which secondary vibration is detected. In FIG. 4, for instance, output response 23 to acceleration along the direction 201 is maximized if the actuator is operating simultaneously at the resonant frequencies of the direction 200 and the direction 201. Maximum output signal is achieved if the two resonant frequency modes (along primary drive axis and secondary axis) are perfectly matched. The symmetry of the acceleration sensor depicted in FIGS. 1, 2, and 5 along with thin-film manufacturing methods provide excellent matching of the primary drive and secondary resonant frequencies; typically within 0.1%. However, a method for electronically tuning the resonant frequencies is desirable to maintain a perfect match throughout manufacturing variations and operating conditions.

A further embodiment of the present invention is a method for tuning the mechanical resonant frequencies of an acceleration sensor, primarily to match the resonant frequencies along the primary actuator axis and secondary vibration detection axis. As discussed above, application of a voltage to the piezoelectric elements causes a mechanical deformation or stress in the material according to the secondary piezoelectric effect. This effect is utilized in all embodiments of the present invention wherein a periodic voltage is applied to selected piezoelectric elements to create a corresponding periodic motion along the primary actuator axis. It is further possible to apply a constant or slowly changing voltage bias to some piezoelectric elements, thereby creating more or less mechanical stress. Such an applied voltage bias shifts the amount of mechanical stress and also shifts the resonant frequency.

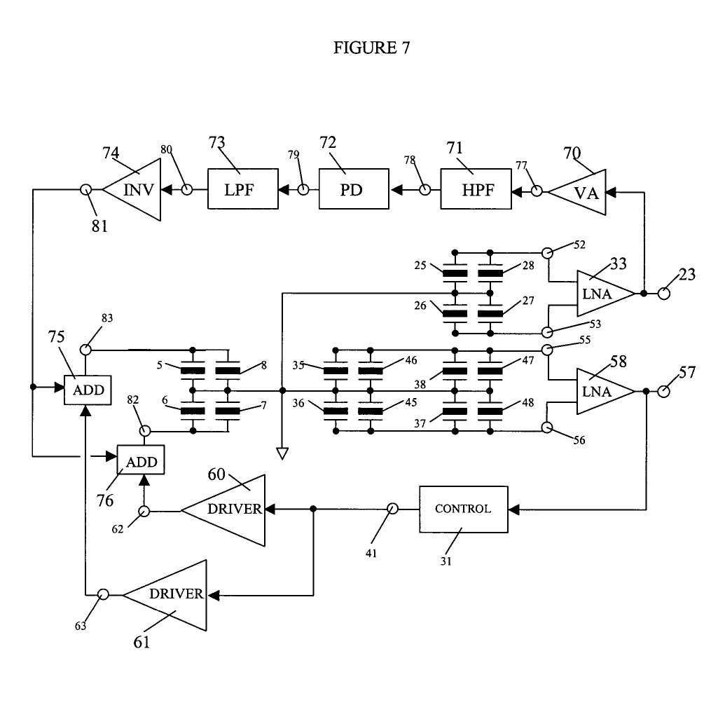

In FIG. 4, for instance (reference to FIG. 2), application of a voltage bias superimposed on the periodic actuator drive electrical signal 62 and 63 shifts the fundamental resonant frequency along the direction 200. In a preferred embodiment of the present invention shown in FIG. 7, a pair of voltage summing circuits 75 and 76 combine a voltage bias 81 with the periodic actuator drive electrical signals 62 and 63. The summing circuits 75 and 76 generate the drive signals 82 and 83. Such summing circuits are common in the field and will not be detailed further. There are many ways to generate the bias voltage 81, including simple analog circuitry, filtering, and digital signal processing.

In a preferred embodiment also shown in FIG. 7, the acceleration output signal 23 is first amplified by a voltage amplifier 70, filtered by a high-pass filter 71, normalized with a peak detect circuit 72, filtered by a low-pass filter 73 and finally inverted by an inverter 74 to generate the voltage bias signal 81. The circuit configuration in FIG. 7 provides a bias voltage 81 that is inversely proportional to the amplitude of secondary vibration along the direction 201. The filter poles in the high-pass filter 71 are set (typically about 1 kHz) to ensure that variations in the signal 23 associated with acceleration motion along the direction 201 (acceleration signal output) do not affect the voltage bias 81. The peak detector 72 converts the periodic signal to a slowly varying signal proportional to the amplitude of the signal 23. The low pass filter 73 poles are set (typically about 0.1 Hz) to ensure that the voltage bias 81 is slowly varying and does not corrupt normal operation of the acceleration sensor.

A further embodiment of the present invention utilizes resonant frequency shift as a measure of acceleration. Similar to the intentional shifting of resonant frequency described above in the context of FIG. 7, application of an acceleration to the solid-state accelerometer of FIGS. 1, 2, and 5 applies a force on the device, thereby shifting a resonant frequency of the device. When the device shown in FIGS. 1 and 2 is operated in the circuit arrangement shown in FIG. 3 or FIG. 4, the output signals 24 and 57 are periodic signals with frequency matching the resonant frequency of the device associated with motion along the direction 200. When an acceleration is applied to the device along the direction 200, the additional stress acts to stiffen the structure and shift the resonant frequency. In this manner, the frequency of the output signals 24 and 57 are measures of acceleration along the direction 200.

Similarly, when the device shown in FIGS. 1 and 5 is operated in the circuit arrangement shown in FIG. 6, 7, or 8, the output signals 65 and 57 are periodic signals with frequency matching the resonant frequency of the device associated with motion along the direction 202. When an acceleration is applied to the device along the direction 202, the additional stress acts to stiffen the structure and shift the resonant frequency. In this manner, the frequency of the output signals 65 and 57 are measures of acceleration along the direction 202.

Using the resonant frequency shift of the acceleration sensor device as a measure of acceleration improves the fidelity of the signal outputs. The differential piezoelectric elements arrangements shown in FIGS. 2 and 5 enable this mode of operation with improved immunity to spurious output signals associated with package strain, electromagnetic interference, and temperature.

Existing vibrating acceleration sensors and embodiments of the present invention described above all generate an output signal at a frequency matching the actuator drive and amplitude that is proportional to the acceleration (such as the output signals 22 and 23 in FIGS. 3, 4, and 6). Resolution with these existing devices is limited by the smallest signal that can be resolved at the output signal 23 relative to the random noise. Furthermore, the amplitude of the output signal is affected by other phenomena such as temperature changes, package strain, and electromagnetic interference. A further subject of the present invention is an alternative method for extracting the acceleration electrical signal above the random noise. In the embodiments of FIGS. 1-7, further post-processing of the acceleration output signals 22 and 23 and actuator reference electrical signals 24, 57, and 65 with a phase-shift detection circuit provides additional immunity to random noise. Furthermore, signal processing of the acceleration output signals 22 and 23 with a phase-shift detection scheme minimizes overall system dependence on factors such as temperature and manufacturing variations. These features provide improved signal fidelity and stability of the acceleration sensor system.

With each of the embodiments shown in FIGS. 1-7, the phase of the acceleration output signals 22 and 23 relative to the actuator reference signal 24, 57, and 65 shifts linearly in response to the acceleration of the sensor. For example, in the embodiment of FIG. 4, the actuator elements 5, 6, 7, and 8 are configured for mechanical oscillation along the direction 200 and the output signal 23 is responsive to acceleration along the direction 201. That is, as the acceleration sensor is accelerated along the direction 201 the phase of the output signal 23 will shift relative to the actuator reference signal 57, the amount of phase shift being in proportion to the acceleration. Similarly, in the embodiment of FIG. 6 (reference to FIG. 5), the actuator elements 109-116 are configured for primary mechanical vibration along the direction 202, and the acceleration output signal 23 phase shifts relative to the actuator reference output signal 65 when the acceleration sensor is subject to acceleration motion along the direction 201. Also in the embodiment of FIG. 6 (reference to FIG. 5), the actuator elements 109-116 are configured for primary mechanical vibration along the direction 202, and the acceleration output signal 22 phase shifts relative to the actuator reference output signal 65 when the acceleration sensor is subject to acceleration motion along the direction 200. A feature of the present invention is an improved method for capturing the acceleration signal that improves resolution, stability, and tolerance to environmental anomalies.

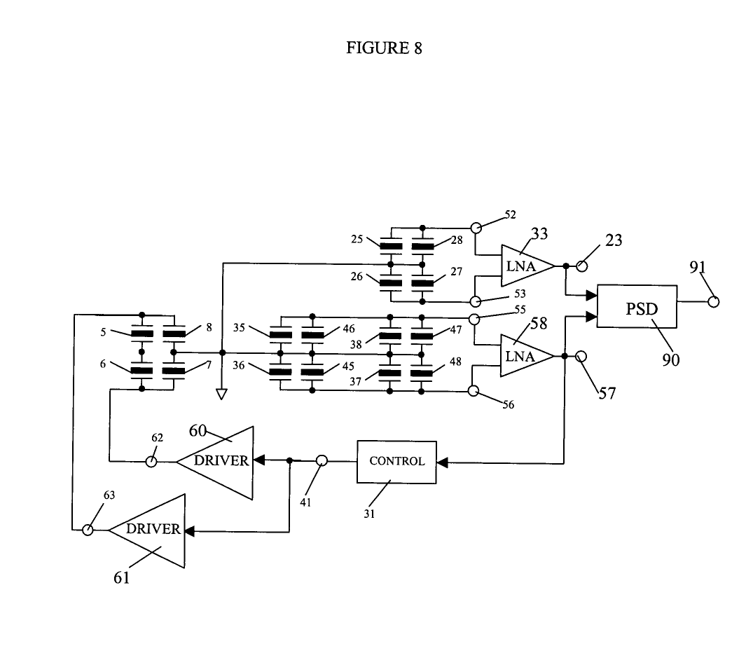

In a preferred embodiment of the present invention shown in FIG. 8, a phase-shift detection circuit 90 compares the phase of acceleration output signal 23 with the phase of actuator reference output signal 57 and generates a third electrical output signal 91 in proportion to the phase difference. Operation of the system in FIG. 8 is generally similar to the embodiment of FIG. 4 with the addition of the phase-shift detection circuit 90. The device depicted in FIGS. 1-2 is connected to the electrical circuit shown in FIG. 8 to achieve both a differential actuator and differential actuator sense.

In the electrical configuration of FIG. 8, the control electronics 31 apply a periodic control signal 41 to a non-inverting voltage driver circuit 60 and an inverting voltage driver circuit 61. The non-inverting voltage driver circuit 60 generates a positive actuator drive electrical signal 62 that is connected to actuator elements 6 and 7. The inverting voltage driver circuit 61 generates a negative actuator drive electrical signal 63 that is connected to actuator elements 5 and 8, and is approximately 180 degrees out of phase with the positive actuator drive electrical signal 62. By the secondary piezoelectric effect, the membrane under the actuator elements 6 and 7 is bent upward (or downward) while the membrane under the actuator elements 5 and 8 is bent downward (or upward). The net result is a tilting of the proof mass 1 (shown in FIG. 1) along the direction 200. As the periodic control signal 41 alternates, the proof mass 1 vibrates along the direction 200 in proportion to and at the oscillation rate of the periodic control signal 41.

If the device is electrically configured as shown in FIG. 8 with proof mass 1 primary vibration along the direction 200 and an acceleration motion is applied to the acceleration sensor along the direction 201, a secondary vibration forms in the direction 201. The secondary vibration is proportional to the magnitude of primary vibration along the direction 200, and the acceleration along the direction 201. The piezoelectric elements 25, 26, 27, and 28 generate differential electrical signals 52 and 53 related to the secondary vibration along the direction 201 that is associated with acceleration along the direction 201.

A low-noise amplifier 33 boosts the level of the differential electrical signals 52 and 53 to create an acceleration output signal 23 which has phase shift relative to actuator reference output 57 proportional to the acceleration motion along the direction 201.

In the embodiment of FIG. 8 (reference to FIGS. 1 & 2), the elements 35-38 and 45-48 create the actuator sense function and are connected in a differential arrangement to generate differential electrical signals 55 and 56 proportional to the primary vibration along the direction 200. Collectively, the elements 35-38 and 45-48 generate the differential actuator sense electrical signals 55 and 56 which are subsequently boosted by a low-noise amplifier 58 to create an output actuator reference signal 57.

Control electronics 31 process the output actuator reference electrical signal 57 by adding appropriate signal gain (or attenuation) and phase shift such that a stable periodic signal 41 is sent to the voltage driver circuits 60 and 61 at the mechanical resonant frequency along the direction 200. This feedback mode of operation provides immunity to temperature variation and other environmental anomalies and improves the overall fidelity of the acceleration sensor performance. Again, the quality of piezoelectric matching and symmetry enable this mode of operation.

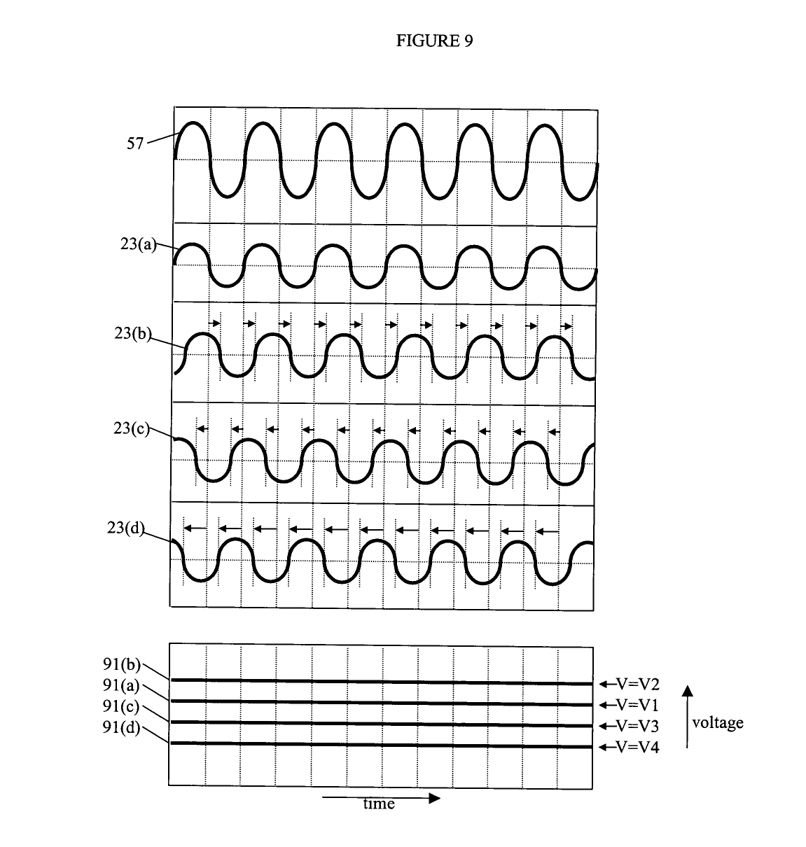

A representation of the phase relationships between acceleration output signal 23 and actuator reference output 57 is shown in FIG. 9 along with the resulting acceleration output 91 from the phase-shift detector 90. The phase of the acceleration output signal 23 relative to the actuator reference output signal 57 shifts in proportion to the acceleration of the sensor. For example, in the embodiment of FIG. 8, the actuator elements 5-8 are configured for primary mechanical vibration along the direction 200 and the output signal 23 is responsive to acceleration motion along the direction 201. When the acceleration sensor is stationary, the phase of the signal 23 approximates the signal 23(a) in FIG. 9 and the acceleration output 91 approximates an output 91(a).

As the acceleration sensor is accelerated along the positive direction 201, the phase of the signal 23 approximates the signal 23(b) in FIG. 9 and acceleration output signal 91 approximates an output 91(b). At an acceleration of R1 in the positive direction 201, the signal 23(b) phase shifts positive relative to the signal 23(a) and the voltage of the output 91(b) shifts positive relative to the output 91(a). As the acceleration sensor is accelerated along the negative direction 201, the phase of the signal 23 approximates the signal 23(c) in FIG. 9 and the acceleration output signal 91 approximates an output 91(c). At the acceleration along the negative direction 201, the signal 23(c) phase shifts negative relative to the signal 23(a) and the voltage of the output 91(c) shifts negative relative to the output 91(a). As the acceleration sensor is accelerated along the negative direction 201 at a higher acceleration, the phase of the signal 23 approximates the signal 23(d) in FIG. 9 and acceleration output signal 91 approximates an output 91(d). At the higher acceleration along the negative direction 201, the output signal 23(d) phase shifts negative relative to both the signal 23(c) and the signal 23(a) and the voltage of the output signal 91(d) shifts negative relative to both the outputs 91(c) and 91(a).

In practice, the actuator reference output 57 provides a phase reference for the acceleration output signal 23. The phase of the output signals 23 and 57 is shown to be zero in FIG. 9 for zero acceleration, but in practice has a nominal phase offset. Nonetheless, the relative phase shift of the output signal 23 when accelerated along the direction 201 is proportional to acceleration. Similarly, by using the phase-shift detector circuit 90, the voltage shift of acceleration output 91 is proportional to the acceleration along the direction 201. The same principle of relative phase shift applies to the embodiments depicted in FIGS. 3, 6, and 7 if the phase-shift detector circuit 90 is implemented; the details will not be repeated here.

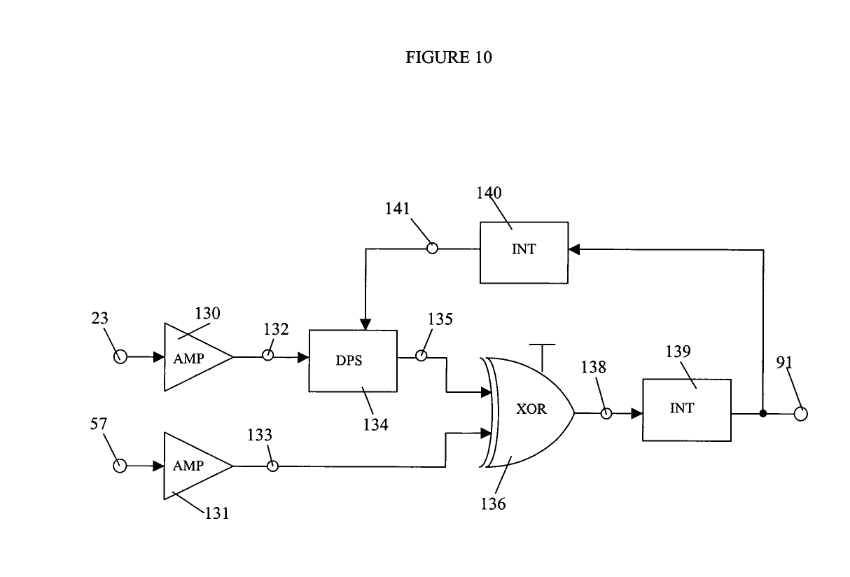

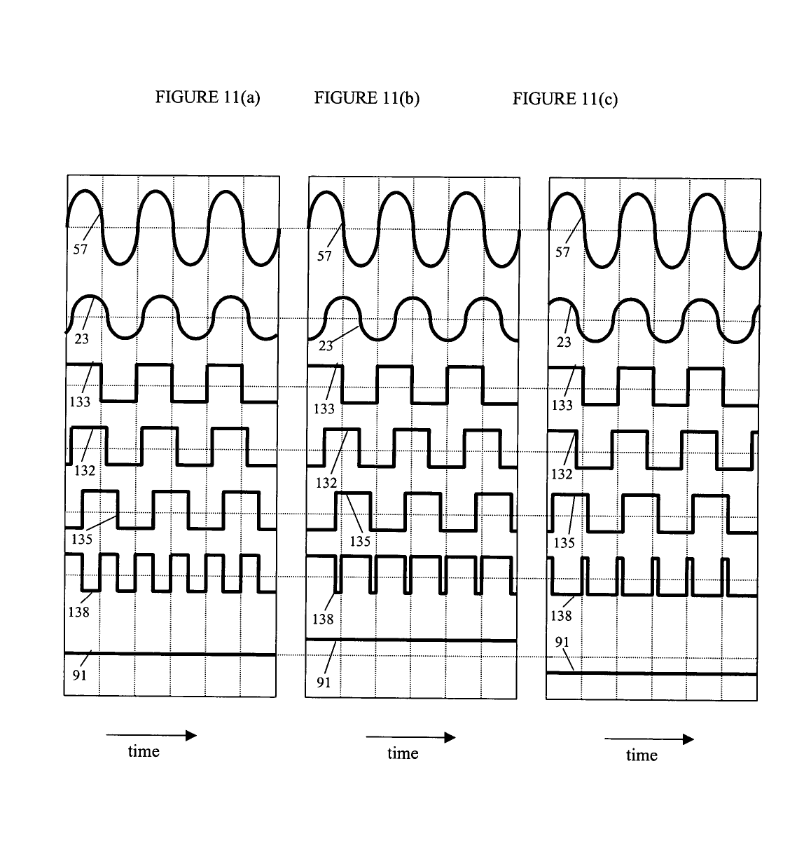

There is a multitude of ways to implement a phase-shift detector circuit 90 in the present invention. Implementations common in the existing devices range from simple analog circuits to complex software-driven digital signal processing (DSP). In a preferred embodiment of the present invention, the analog circuit shown in FIG. 10 performs the phase-shift detector (PSD) function 90 and generates the acceleration output signal 91 shown in FIG. 8. Electrical signals internal to the PSD 90 of FIG. 10 are shown in FIG. 11.

In FIG. 10, a pair of amplifiers 130 and 131 boost the level of acceleration output signal 23 and actuator reference 57 to generate digitized signals 132 and 133. A digital phase-shifter circuit 134 applies a phase shift to signal 132 to generate signal 135. The purpose of using the phase-shifter circuit 134 is to null out systematic phase offset of the signal 23 relative to the signal 57. That is, when the acceleration sensor is stationary, the signals 23 and 57 are generally not phase matched. It may be desirable from a system performance standpoint to have the nominal value of acceleration output 91 set at a predetermined voltage level and the phase-shifter circuit 134 provides this capability.

The digital signals 135 and 133 are processed through an Exclusive-OR (XOR) digital logic gate 136 that generates an output signal 138 that is logical “1” when either the signal 135 is positive or the signal 133 is positive. When both the signals 135 and 133 are negative, or when both the signals 135 and 133 are positive, output signal 138 is logical “0”.

An integrator circuit 139 averages the voltage level over time of signal 138 to generate the acceleration output 91. The filter poles of the integrator circuit 139 are set depending on the application requirements. A second integrator circuit 140 further processes the acceleration output 91 to provide feedback signal 141 to the phase shifter 134. The feedback path through the integrator 140 to the phase shifter 134 provides a means for stabilizing the acceleration output 91 to a desired level over a long time period. The filter poles of the integrator circuit 140 are set depending on the application requirements. As an example, if acceleration changes only between 0.01 Hz and 100 Hz are important for a given application, the filter poles of integrator 139 may be set near 100 Hz and the filter poles of integrator 140 may be set near 0.01 Hz. In effect, integrator 139 provides a low-pass filter for the acceleration output 91, and integrator 140 provides a high-pass filter for the acceleration output 91.

There are many ways to implement a phase-shift detection circuit that provide an electrical acceleration output signal 91 (in FIG. 8) in proportion to the relative phase between two periodic input signals 23 and 57 (in FIG. 8). The preferred embodiment shown in FIG. 10 and described above is one such method and is not intended to limit the scope of the present invention.

From the above description and drawings, it will be understood by those of ordinary skill in the art that the particular embodiments shown and described are for purposes of illustration only and are not intended to limit the scope of the present invention. Those of ordinary skill in the art will recognize that the present invention may be embodied in other specific forms without departing from its spirit or essential characteristics. References to details of particular embodiments are not intended to limit the scope of the invention.

What is claimed is:

1. A solid-state device having a thin-film piezoelectric material forming a plurality of piezoelectric elements, a first set of the plurality of piezoelectric elements generating a force, and a second set of the plurality of piezoelectric elements generating an electrical signal in proportion to both the force and an acceleration of the solid-state device while rejecting spurious noise.

2. A solid-state acceleration sensor device, comprising:
a first set of piezoelectric elements;
a second set of piezoelectric elements;
wherein the first set of piezoelectric elements including a piezoelectric material and being actuated by an electrical signal, wherein when the electrical signal is applied on the piezoelectric material, the second set of piezoelectric elements senses the acceleration of the solid-state acceleration sensor device.

3. The solid-state acceleration sensor device of claim 2, wherein the first and second sets of piezoelectric elements are configured on a thin-film piezoelectric material.

4. The solid-state acceleration sensor device of claim 2, further comprising a third set of piezoelectric elements that sense a force generated by the first set of the piezoelectric elements.

5. The solid-state acceleration sensor device of claim 4, wherein a signal sensed by at least one set of the second and third sets of piezoelectric elements is fed back to the first set of piezoelectric elements.

6. The solid-state acceleration sensor device of claim 2, wherein the electrical signal applied on the first set of piezoelectric elements is variable to modify a mechanical resonant frequency of the solid-state acceleration sensor device.

7. The solid-state acceleration sensor device of claim 2, wherein the piezoelectric material of the first set of the piezoelectric elements includes conductive electrodes placed on approximately opposite sides such that application of the electrical signal to the conductive electrodes causes a longitudinal variation of the piezoelectric material.

8. The solid-state acceleration sensor device of claim 2, wherein the piezoelectric material is a thin-film piezoelectric material with a thickness of less than 10 microns and includes conductive electrodes placed on approximately opposite sides such that application of the electrical signal to the conductive electrodes causes a longitudinal variation of the thin-film piezoelectric material.

9. The solid-state acceleration sensor device of claim 2, wherein the piezoelectric material is a thin-film piezoelectric material comprising a family of Lead-Zirconate-Titanate (PZT) compounds.

10. The solid-state acceleration sensor device of claim 2, wherein the solid-state device includes a semi-rigid member fixed along a first edge to a proof mass and fixed along a second edge to an outer base.

11. The solid-state acceleration sensor device of claim 10, wherein the semi-rigid support comprises a tuning fork.

12. The solid-state acceleration sensor device of claim 10, wherein the semi-rigid support comprises a vibrating cup.

13. The solid-state acceleration sensor device of claim 10, wherein the semi-rigid support comprises a comb structure.

14. The solid-state acceleration sensor device of claim 10, wherein the semi-rigid support comprises an annular ring.

15. A method of sensing an acceleration of a solid-state device formed by a plurality of thin-film piezoelectric elements having a first set of piezoelectric elements, a second set of piezoelectric elements, and a third set of piezoelectric elements, comprising the steps of:
actuating the first set of piezoelectric elements by a first electrical signal; and
sensing acceleration by the second and third sets of piezoelectric elements while rejecting spurious noise.

16. The method of claim 15, further comprising the steps of generating a second electrical signal by the second set of piezoelectric elements proportional to a mechanical force along a first direction, and generating a third electrical signal by the third piezoelectric elements proportional to the mechanical force along a second direction, wherein the second direction is orthogonal to the first direction, and wherein phase of the third electrical signal shifts relative to the second electrical signal in response to acceleration of the solid-state device along said second direction.

17. The method of claim 15, further comprising the steps of connecting the second and third electrical signals to a phase-shift detection circuit, and generating an electrical output signal in proportion to a shift of the phase.

18. An acceleration sensor, comprising:
a proof mass;
a first piezoelectric element for generating a force on the proof mass along a first direction by a first electrical signal;
a second piezoelectric element for generating a second electrical signal in proportion to the force on the proof mass along the first direction;
a third piezoelectric element for generating a third electrical signal in proportion to the force on the proof mass along a second direction; and
an electrical circuit connected to the first piezoelectric element for applying the first electrical signal.

19. The acceleration sensor of claim 18, further comprising a phase shift detection circuit that generates an electric output signal in proportion to a phase shift between the second and third electrical signals.

20. The acceleration sensor of claim 18, further comprising a feedback circuit for feeding back a signal sensed by at least one set of the second and third sets of the piezoelectric elements.

21. A method of sensing an acceleration of a solid-state device formed by a plurality of thin-film piezoelectric elements having a first set of piezoelectric elements and a second set of piezoelectric elements, comprising the steps of:
actuating the first set of piezoelectric elements by a first electrical signal;
sensing vibration of the solid-state device by the second set of piezoelectric elements; and
feeding back a portion of a sensed signal generated by the second set of piezoelectric elements to the first set of piezoelectric elements so as to actuate the first set of piezoelectric elements at a resonant frequency of the solid-state device.

22. The method of claim 21, further comprising a step of measuring frequency of the first electrical signal as a measure of acceleration of the solid-state device.

23. An acceleration sensor, comprising:
a proof mass;
a first plurality of piezoelectric elements for generating a force on the proof mass along a first direction by a first electrical signal;
a second plurality of piezoelectric elements for generating a second electrical signal in proportion to the force on the proof mass along the first direction; and
an electrical circuit connected to the first plurality of piezoelectric elements for applying the first electrical signal.

24. The acceleration sensor of claim 23, further comprising a feedback circuit for feeding back a portion of the second electrical signal to the first plurality of piezoelectric elements.

25. The acceleration sensor of claim 23, wherein the first and second plurality of piezoelectric elements are made of a thin-film piezoelectric material with a thickness of less than 10 microns and conductive electrodes placed on approximately opposite sides of the piezoelectric material such that application of an electrical signal to the conductive electrodes causes a longitudinal variation of the thin-film piezoelectric material.
